(19) United States
(12) Patent Application Publication
(10) Pub. No.: US 2024/0075836 A1
(43) Pub. Date: Mar. 7, 2024

(54) Charging Pile

(71) Applicant: SHENZHEN WINLINE TECHNOLOGY CO., LTD., Shenzhen (CN)

(72) Inventors: Yunliang Xie, Shenzhen (CN); Bin Luo, Shenzhen (CN); Shuisheng Chen, Shenzhen (CN); Jianguo Zhu, Shenzhen (CN)

(21) Appl. No.: 18/505,579

(22) Filed: Nov. 9, 2023

Related U.S. Application Data
(63) Continuation of application No. PCT/CN2021/142389, filed on Dec. 29, 2021.

(30) Foreign Application Priority Data
Sep. 6, 2021 (CN) 202122132052.2

(51) Int. Cl. B60L 53/31; H02J 7/00

(52) U.S. Cl. CPC B60L 53/31; H02J 7/0042

(57) ABSTRACT

A charging pile is provided and includes a housing and a charging module; the housing defines an accommodating cavity, the housing defines an air inlet and an air outlet, the charging module is accommodated in the accommodating cavity, the charging module has a first side-surface and a second side-surface opposite to the first side-surface, and a third side-surface and a fourth side-surface opposite to the third side-surface, the air inlet is located at one side of the first side-surface away from the second side-surface, the air outlet is located at one side of the second side-surface away from the first side-surface, air enters the accommodating cavity through the air inlet, flows to the third side-surface along the first side-surface to flow into the charging module, flows out of the charging module from the fourth side-surface to the second side-surface, and flows out of the accommodating cavity through the air outlet.

### CROSS-REFERENCE TO RELATED APPLICATION(S)

This application is a continuation of International Application No. PCT/CN2021/142389, filed Dec. 29, 2021, which claims priority to and the benefit of Chinese Patent Application No. 202122132052.2, filed Sep. 6, 2021, the entire disclosures of both of which are hereby incorporated by reference.

### TECHNICAL FIELD

This disclosure relates to the field of new-energy technology, and in particular to a charging pile.

### BACKGROUND

With increasing popularity of direct current (DC) charging piles of vehicles, many charging piles are installed in residential areas, and problems of noise disturbance from charging piles are more and more prominent. A common practice of an existing charging pile is to additionally arrange a sound insulation cotton on a side wall simply, but a noise reduction effect is not obvious; or a complex internal structure is designed for noise reduction, but a heat dissipation effect of the charging pile is relatively poor.

### SUMMARY

A charging pile is provided in the present disclosure. The charging pile defines a housing and a charging module. The housing defines an accommodating cavity. The housing defines an air inlet and an air outlet. The charging module is accommodated in the accommodating cavity. The charging module has a first side-surface and a second side-surface opposite to the first side-surface, and a third side-surface and a fourth side-surface opposite to the third side-surface. The air inlet is located at one side of the first side-surface away from the second side-surface, and the air outlet is located at one side of the second side-surface away from the first side-surface. Air enters the accommodating cavity through the air inlet, flows to the third side-surface along the first side-surface to flow into the charging module, flows out of the charging module from the fourth side-surface to the second side-surface, and flows out of the accommodating cavity through the air outlet.

### BRIEF DESCRIPTION OF THE DRAWINGS

To more clearly describe implementations in the present disclosure or technical solutions in related art, the accompanying drawings that need to be used in description of implementations or the related art will be briefly introduced below. Apparently, the accompanying drawings in the following description are only some implementations in the present disclosure, and those of ordinary skill in the art may also obtain other accompanying drawings based on these accompanying drawings without creative effort.

FIG. 1 is a schematic perspective structural diagram of a charging pile according to an embodiment.

FIG. 2 is a schematic structural diagram of an internal air duct of a charging pile according to an embodiment.

FIG. 3 is a schematic structural diagram of a first wall-plate according to an embodiment.

FIG. 4 is a schematic structural diagram of a second wall-plate according to an embodiment.

FIG. 5 is a partial schematic structural diagram of a charging pile according to an embodiment.

FIG. 6 is a partial schematic structural diagram of a charging pile according to an embodiment.

### DETAILED DESCRIPTION

Technical solutions of implementations in the present disclosure will be described clearly and completely below with reference to accompanying drawings in implementations of the present disclosure. Apparently, implementations described herein are merely some implementations, rather than all implementations, of the present disclosure. Based on implementations of the present disclosure, all other implementations obtained by those of ordinary skill in the art without creative effort shall fall within the protection scope of the present disclosure.

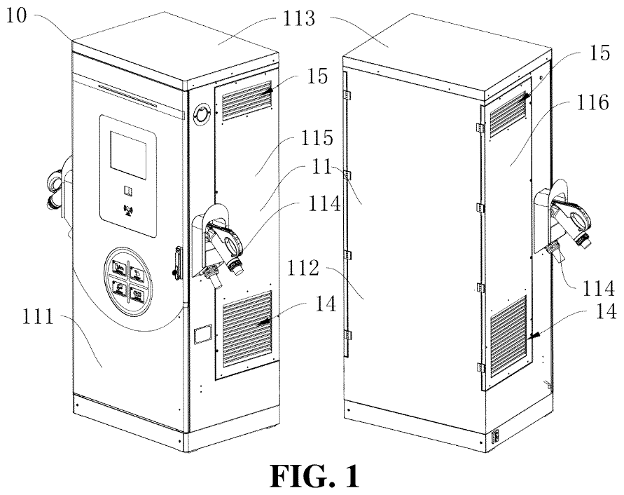

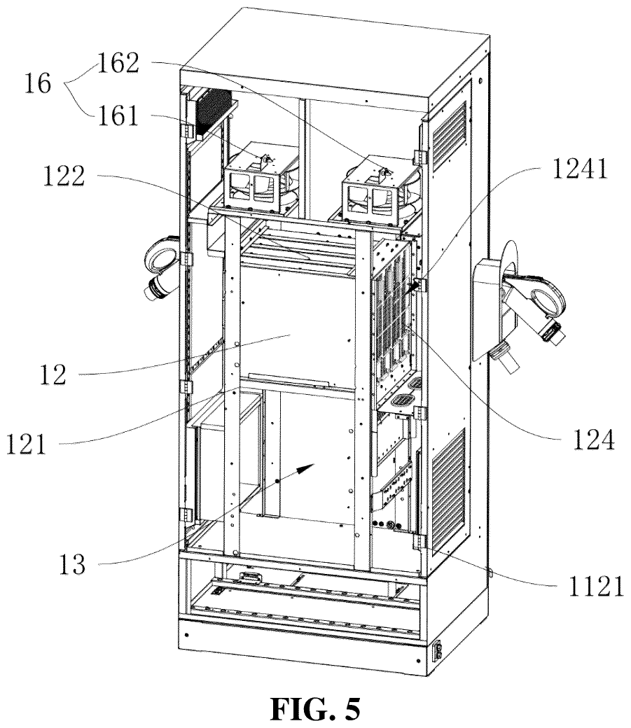

Referring to FIG. 1 and FIG. 5, a charging pile 10 is provided in an embodiment. The charging pile 10 includes a housing 11 and a charging module 12. The housing 11 defines an accommodating cavity 13, the housing 11 defines an air inlet 14 and an air outlet 15, and the charging module 12 is accommodated in the accommodating cavity 13, thereby realizing an external charging function and protecting the charging module 12.

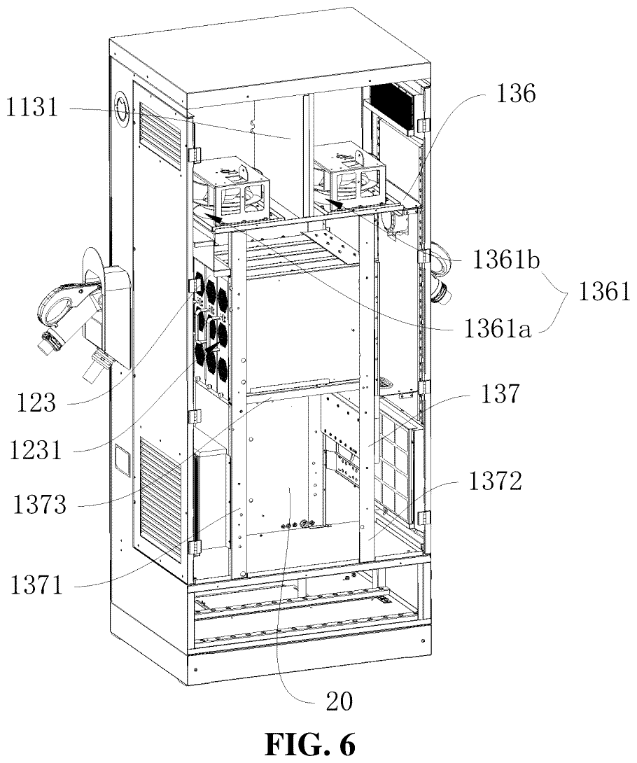

In an embodiment, referring to FIG. 1, FIG. 5, and FIG. 6, the charging module 12 has a first side-surface 121 and a second side-surface 122 opposite to the first side-surface 121, and a third side-surface 123 and a fourth side-surface 124 opposite to the third side-surface 123. The air inlet 14 is located at one side of the first side-surface 121 away from the second side-surface 122. The air outlet 15 is located at one side of the second side-surface 122 away from the first side-surface 121. Air enters the accommodating cavity 13 through the air inlet 14, flows to the third side-surface 123 along the first side-surface 121 to flow into the charging module 12, flows out of the charging module 12 from the fourth side-surface 124 to the second side-surface 122, and flows out of the accommodating cavity 13 through the air outlet 15.

Specifically, the housing 11 includes a front plate 111 with an operational function, a back plate 112 for closing the accommodating cavity 13, a top plate 113, and gun bases 114. The front plate 111 may be configured to mount an intelligent operation module to facilitate operation of the charging pile. The gun bases 114 are located at two sides of the housing 11 and each are configured to charge an external electricity-consumption device.

Further, the charging module 12 defines a first opening 1231 and a second opening 1241, the first opening 1231 is located on the third side-surface 123, and the second opening 1241 is located on the fourth side-surface 124. The inside of the charging module 12 communicates with the accommodating cavity 13 through the first opening 1231 and the second opening 1241. The noise of the charging module 12 is mainly generated at the first opening 1231. A propagation patch of the noise generated is through the third side-surface 123 and the first side-surface 121 to the air inlet 14 in sequence, and finally out of the accommodating cavity 13 through the air inlet 14.

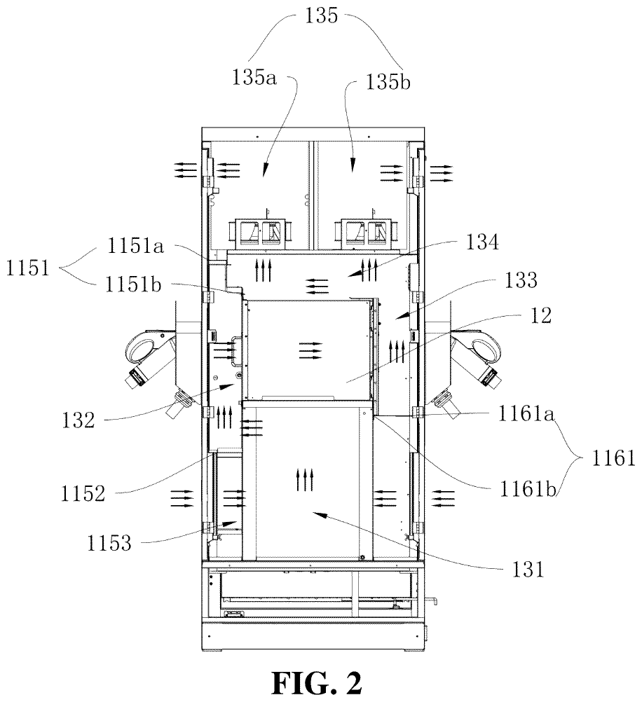

In this embodiment, referring to FIG. 2, the accommodating cavity 13 may include a first cavity 131, a second cavity 132, a third cavity 133, a fourth cavity 134, and a fifth cavity 135. The first cavity 131 communicates with the outside through the air inlet 14; the second cavity 132 communicates with the first cavity 131, and communicates with the inside of the charging module 12 through the first opening 1231; the third cavity 133 communicates with the fourth cavity 134, and communicates with the inside of the charging module 12 through the second opening 1241; and the fifth cavity 135 communicates with the outside through the air outlet 15, and communicates with the fourth cavity 134. Further, since the charging module 12 has a good blocking effect on the noise inside the charging module 12, it is difficult for the noise to pass through the inside of the charging module 12 to the third cavity 133 through the second opening 1241, and then be propagated out of the charging pile 10 through the air outlet 15. In this way, a main propagation path of the noise is from the first opening 1231 to the second cavity 132, and then out of the charging pile 10 from the first cavity 131 through the air inlet 14.

For the charging pile 10 provided in this embodiment, the charging module 12 is disposed between the air inlet 14 and the air outlet 15, so that the noise generated when the charging module 12 operates can be reflected multiple times between the inner wall of the housing 11 and four side surfaces of the charging module 12. Therefore, the noise intensity is weakened, and the noise has been greatly attenuated when being propagated out of the air inlet 14 and the air outlet 15. In addition, air entering the accommodating cavity 13 can flow around the charging module 12, and the noise is also reduced in a good heat dissipation environment established.

In an embodiment, referring to FIG. 2, the charging pile 10 includes a first partition 1151. The first partition 1151 has a first end 1151a and a second end 1151b opposite to the first end 1151a. The first end 1151a is connected to the housing 11, and the second end 1151b is connected to a junction between the second side-surface 122 and the third side-surface 123. Specifically, the first partition 1151 may be a ‘Z’-shaped plate. The first partition 1151, the third side-surface 123, and the housing 11 cooperatively define the second cavity 132. In other embodiments, the first partition 1151 may also be a wavy plate. The first partition 1151 is connected to the housing 11 and the charging module 12, and is configured to close the second cavity 132. Further, the first partition 1151 may be made of metal or other non-metal materials.

Further, referring to FIG. 2, FIG. 5, and FIG. 6, air flowing to the third side-surface 123 along the first side-surface 121 is blocked by the first partition 1151 from flowing to the second side-surface 122, and turns 90° to enter the inside of the charging module 12 through the first opening 1231. The noise generated at the first opening 1231 will be propagated into the first cavity 131 in a reverse direction of the air after multiple reflections in the second cavity 132. In this way, the noise is attenuated for the first time in the propagation.

In an embodiment, referring to FIG. 1, FIG. 2, FIG. 5, and FIG. 6, the charging pile 10 further includes a second partition 1161. The second partition 1161 has a third end 1161a and a fourth end 1161b opposite to the third end 1161a, the third end 1161a is connected to the housing 11, and the fourth end 1161b is connected to a junction between the first side-surface 121 and the fourth side-surface 124. Specifically, the second partition 1161 may be an T-shaped plate. The second partition 1161, the first side-surface 121, and the housing 11 cooperatively define the first cavity 131 at one side of the second partition 1161 facing the air inlet 14. The second partition 1161, the fourth side-surface 124, and the housing 11 cooperatively define the third cavity 133 at one side of the second partition 1161 facing the air outlet 15. In other embodiments, the second partition 1161 may also be an irregularly shaped plate. Further, the second partition 1161 may be made of metal or other non-metal materials.

Further, air flowing into the charging pile 10 through the air inlet 14 is blocked by the second partition 1161 from flowing to the fourth side-surface 124, and flows along the first side-surface 121; and air flowing out of the charging module 12 through the second opening 1241 is also blocked by the second partition 1161, and after flowing to the second side-surface 122 along the fourth side-surface 124, and the air flows out of the charging pile 10 through the air outlet 15. However, the noise generated at the second cavity 132 is reflected multiple times in the first cavity 131 and then propagated to the air inlet 14 in a reverse direction of the air, and then be propagated out of the charging pile 10 through the air inlet 14. Therefore, the noise is attenuated for the second time in the propagation, and hot air flowing out of the charging module through the second opening 1241 is prevented from flowing back to the first cavity 131.

In an embodiment, the housing 11 includes a first wall-plate 115 and a second wall-plate 116. The air inlet 14 includes a first air inlet 141 and/or a second air inlet 142. The third side-surface 123 faces the first wall-plate 115, and the fourth side-surface 124 faces the second wall-plate 116. The first air inlet 141 is located on the first wall-plate 115, and the second air inlet 142 is located on the second wall-plate 116.

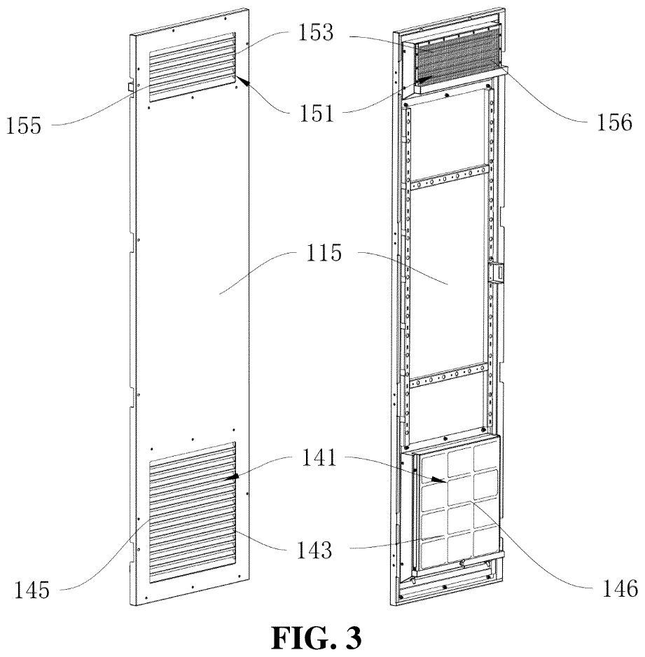

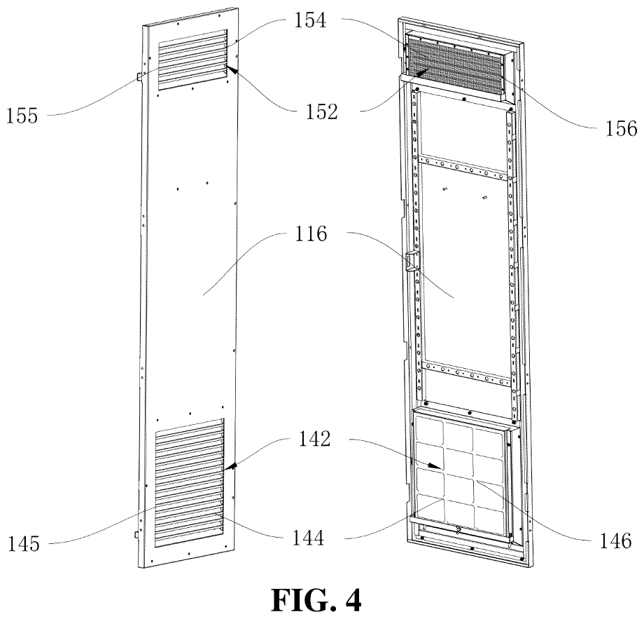

Referring to FIG. 2, FIG. 3, FIG. 4, and FIG. 5, the first wall-plate 115 and the second wall-plate 116 may be panels of the same size. The first wall-plate 115 defines the first air inlet 141. The second wall-plate 116 defines the second air inlet 142. The first air inlet 141 and the second air inlet 142 are both rectangles of the same size. The first air inlet 141 and the second air inlet 142 each communicate with the first cavity 131. Further, air laterally flowing into the charging pile 10 through the first air inlet 141 and air laterally flowing into the charging pile 10 through the second air inlet 142 are converged in the first cavity 131, and turn 90° to flow towards the first side-surface 121. In this way, with definition of the two air inlets 14, in the closed charging pile 10, sufficient air circulation can be ensured, the good heat dissipation effect with the same noise reduction effect can also be ensured.

In this embodiment, a first air-inlet member 143 is disposed at the first air inlet 141, and a second air inlet member 144 is disposed at the second air inlet 142. The first air-inlet member 143 and the second air-inlet member 144 each are of the same size as the air inlet 14. The first air-inlet member 143 is detachably connected to the first wall-plate 115, and the second air-inlet member 144 is detachably connected to the second wall-plate 116. The first air-inlet member 143 may include an air-inlet louver 145 at one side of the first air-inlet member 143 facing the outside of the charging pile 10, and the second air-inlet member 144 may include an air-inlet louver 145 at one side of the second air-inlet member 144 facing the outside of the charging pile 10. In other embodiments, the first air-inlet member 143 may also include a window screen at one side of the first air-inlet member 143 facing the outside of the charging pile 10, and the second air-inlet member 144 may also include a window screen at one side of the second air-inlet member 144 facing the outside of the charging pile 10. The first air-inlet member 143 may include an air-inlet filter layer 146 at one side of the first air-inlet member 143 facing the inside of the charging pile 10, and the second air-inlet member 144 may include an air-inlet filter layer 146 at one side of the second air-inlet member 144 facing the inside of the charging pile 10. With arrangement of the air-inlet member, solid impurities such as an ash layer in the air can be effectively filtered, so as to prevent the solid impurities from affecting normal operation of the charging module 12 after flowing into the charging module 12 along with the air; and a manner of detachable connection also facilitates replacement of the air-inlet member after sufficient solid impurities are filtered.

In an embodiment, referring to FIG. 2, FIG. 3, and FIG. 4, the charging pile 10 further includes a third partition 1152. The third partition 1152 is connected to the first wall-plate 115. The third partition 1152 and the first wall-plate 115 cooperatively define an air-inlet duct 1153. The air-inlet duct 1153 communicates with the first air inlet 141. The third partition 1152 is spaced apart from the first side-surface 121. Further, the third partition 1152 may be made of metal or other non-metal materials.

Specifically, the third partition 1152 is disposed around a periphery of the air-inlet filter layer 146 of the first air-inlet member 143. Air flowing through the first air inlet 141 and air flowing through the second air inlet 142 are converged in the first cavity 131 under the guidance of the third partition 1152. In addition, due to a distance between the third partition 1152 and the first side-surface 121, sufficient air can be ensured to flow into the second cavity 132. At one side of the third partition 1152, the third partition 1152 faces the first partition 1151 at one side of the third partition 1152, and the third partition 1152 and the first partition 1151 cooperatively define the second cavity 132, so that the noise generated at the first opening 1231 may be repeatedly reflected between the first partition 1151, the third partition 1152, and the housing 11, and this reflection is beneficial to noise attenuation.

In an embodiment, referring to FIG. 3 and FIG. 4, the air outlet 15 includes a first air outlet 151 and/or a second air outlet 152. The first air outlet 151 is located on the first wall-plate 115. The second air outlet 152 is located on the second wall-plate 116. Specifically, the first air outlet 151 is located at the other end of the first wall-plate 115 opposite to the first air inlet 141. The second air outlet 152 is located at the other end of the second wall-plate 116 opposite to the second air inlet 142. In this way, the air inlet 14 and the air outlet 15 are respectively disposed at two ends of the housing 11, so that there is sufficient circulation space for the air in the accommodating cavity, air circulation is accelerated, and the heat dissipation effect of the charging pile 10 itself is improved.

In this embodiment, a first air-outlet member 153 is disposed at the first air outlet 151, and a second air-outlet member 154 is disposed at the second air outlet 152. The first air-outlet member 153 and the second air-outlet member 154 each are of the same size as the air outlet 15. The first air-outlet member 153 is detachably connected to the first wall-plate 115, and the second air-outlet member 154 is detachably connected to the second wall-plate 116. The first air-outlet member 153 may include an air-outlet louver 155 at one side of the first air-outlet member 153 facing the outside of the charging pile 10, and the second air-outlet member 154 may include an air-outlet louver 155 at one side of the second air-outlet member 154 facing the outside of the charging pile 10. In other embodiments, the first air-outlet member 153 may also include a window screen at one side of the first air-outlet member 153 facing the outside of the charging pile 10, and the second air-outlet member 154 may also include a window screen at one side of the second air-outlet member 154 facing the outside of the charging pile 10. The first air-outlet member 153 may include an air-outlet filter layer 156 at one side of the first air-outlet member 153 facing the inside of the charging pile 10, and the second air-outlet member 154 may include an air-outlet filter layer 156 at one side of the second air-outlet member 154 facing the inside of the charging pile 10. With arrangement of the air-outlet member, solid impurities such as an ash layer in the air can be effectively filtered, so as to prevent the solid impurities from affecting normal operation of the charging module 12 after flowing into the charging module 12 along with the air; and a manner of detachable connection also facilitates replacement of the air-outlet member after sufficient solid impurities are filtered.

In an embodiment, referring to FIG. 3, FIG. 4, and FIG. 5, the first wall-plate 115 and the second wall-plate 116 each are an openable door. Specifically, a hinge 1121 is disposed at a junction between the first wall-plate 115 and the back plate 112, and a hinge 1121 is disposed at a junction between the second wall-plate 116 and the back plate 112. Opening and closing of the hinge 1121 can control opening and closing of the first wall-plate 115 or opening and closing of the second wall-plate 116, thereby facilitating cleaning the internal environment of the charging pile 10, and facilitating replacement and repair when the charging module 12 has a fault.

In an embodiment, referring to FIG. 5 and FIG. 6, the charging pile 10 further includes a centrifugal fan 16. The centrifugal fan is located between the second side-surface 122 and the air outlet 15. Specifically, a support plate 136 is further disposed in the accommodating cavity 13. The support plate 136 faces the second side-surface 122, and the centrifugal fan 16 is disposed on the support plate 136. The support plate 136 has one end connected to the first partition 1151, and the other end connected to the housing 11. The support plate 136, the second side-surface 122, the first partition 1151, and the housing 11 cooperatively define the fourth cavity 134. The support plate 136 and the top plate 113 of the housing 11 also cooperatively define the fifth cavity 135.

Further, the support plate 136 defines a vent 1361 corresponding to the centrifugal fan 16. The centrifugal fan 16 is configured to draw air in the fourth cavity 134 to the fifth cavity 135 through the vent 1361, so that the fourth cavity 134 is under the negative pressure. Then, air in the third cavity 133, the second cavity 132, and the first cavity 131 flows under the negative pressure, so that a stable air-flow direction is defined from the first cavity 131 to the fifth cavity 135 in the charging pile 10. The air in the fifth cavity 135 may flow out of the charging pile 10 through the air outlet 15, so that air circulation is formed in the charging pile 10 and in the external environment, which is beneficial to continuous heat dissipation of the charging pile 10.

Further, a noise source, i.e., the centrifugal fan 16, is disposed in the fifth cavity 135. An inner wall of the fifth cavity 135 is covered with the sound insulation cotton 20. The fifth cavity 135 has a large space. An inner surface area of the fifth cavity 135 is greater than an area of the first air outlet 151 and the second air outlet 152. Due to a relatively large area difference between the inner surface area of the fifth cavity 135 and the area of the first air outlet 151 and the second air outlet 152, a noise of the centrifugal fan 16 is greatly attenuated, and only a small amount of noise is propagated out of the charging pile 10 through the air outlet 15.

Due to relatively large inner space of the charging pile 10, when the centrifugal fan 16 operates, a relatively large air flow is formed, and therefore, the centrifugal fan 16 is required to have a wind pressure resistance capability. In this embodiment, the centrifugal fan 16 is a wind pressure resistant and stable centrifugal fan.

In this embodiment, referring to FIG. 2, FIG. 5, and FIG. 6, a first centrifugal fan 161 and a second centrifugal fan 162 are provided, and a fourth partition 1131 is mounted between the first centrifugal fan 161 and the second centrifugal fan 162. The fourth partition 1131 is connected to the support plate 136, and the front plate 111 and the top plate 113 of the charging pile 10. The fourth partition 1131 partitions the fifth cavity 135 into a first chamber 135a and a second chamber 135b. The first centrifugal fan 161 is disposed on part of the support plate 136 that defines the first chamber 135a and a corresponding first vent 1361a. The second centrifugal fan 162 is disposed on part of the support plate 136 that defines the second chamber 135b and a corresponding second vent 1361b.

In an embodiment, referring to FIG. 6, the charging pile 10 further includes a frame 137. The frame 137 is configured to fix the charging module 12. Specifically, the frame 137 is located in the accommodating cavity 13. The frame 137 includes a first support-portion 1371 and a second support-portion 1372. The first support-portion 1371 has one end connected to the support plate 136, and the other end connected to the bottom of the charging pile 10. The second support-portion 1372 has one end connected to the support plate 136, and the other end connected to the bottom of the charging pile 10. The first support-portion 1371 is close to the first wall-plate 115. The second support-portion 1372 is close to the second wall-plate 116. The first support-portion 1371 is connected to the second support-portion 1372 through two cross bars 1373. The third partition 1152 is connected to the first support-portion 1371 at one end of the third partition 1152 away from the first wall-plate 115, so that the third partition 1152 is fixed.

In an embodiment, referring to FIG. 6, sound insulation cotton 20 is further disposed in the accommodating cavity 13. The sound insulation cotton 20 is configured to absorb the noise in the accommodating cavity 13. Specifically, the inner wall of the housing 11 may be covered with sound insulation cotton 20 accounting for more than 80% of the area of the inner wall of the housing 11. Each of the first partition 1151 and the second partition 1161 may be covered with the sound insulation cotton 20 all around, or part of the surface of each of the first partition 1151 and the second partition 1161 may be covered with the sound insulation cotton 20. Each of the inner wall of the third partition 1152 and the outer wall of the third partition 1152 may be covered with the sound insulation cotton 20, or part of the surface of each of the inner wall of the third partition 1152 and the outer wall of the third partition 1152 may be covered with the sound insulation cotton 20. When the noise is reflected in the accommodating cavity 13, the noise may be absorbed by the sound insulation cotton 20 covered on a reflecting surface, so as to reduce the noise propagated out of the charging pile 10.

Further, a wall surface of the fifth cavity 135 may be covered with the sound insulation cotton 20 accounting for more than 90% of the area of the wall surface of the fifth cavity 135. The fourth partition 1131 may be covered with the sound insulation cotton 20 all around. In this way, the noise generated by the centrifugal fan 16 is reflected and propagated in the fifth cavity 135 coated with the sound insulation cotton 20, and the sound insulation cotton 20 further absorbs the noise reaching the reflecting surface, thereby realizing the effect of noise attenuation.

The above disclosure is merely a preferred implementation of the present disclosure, and cannot be used to limit the scope of the present disclosure. Those of ordinary skill in the art can understand all or part of processes for implementing the above embodiments, and equivalent changes made according to the claims of the present disclosure still fall in the scope of the present disclosure.

What is claimed is:

1. A charging pile comprising a housing and a charging module; wherein:
the housing defines an accommodating cavity, the housing defines an air inlet and an air outlet, the charging module is accommodated in the accommodating cavity, the charging module has a first side-surface and a second side-surface opposite to the first side-surface, and a third side-surface and a fourth side-surface opposite to the third side-surface, the air inlet is located at one side of the first side-surface away from the second side-surface, the air outlet is located at one side of the second side-surface away from the first side-surface, and
air enters the accommodating cavity through the air inlet, flows to the third side-surface along the first side-surface to flow into the charging module, flows out of the charging module from the fourth side-surface to the second side-surface, and flows out of the accommodating cavity through the air outlet.

2. The charging pile of claim 1, further comprising a first partition, wherein the first partition has a first end and a second end opposite to the first end, the first end is connected to the housing, and the second end is connected to a junction between the second side-surface and the third side-surface.

3. The charging pile of claim 1, further comprising a second partition, wherein the second partition has a third end and a fourth end opposite to the third end, the third end is connected to the housing, and the fourth end is connected to a junction between the first side-surface and the fourth side-surface.

4. The charging pile of claim 1, wherein the housing comprises a first wall-plate and a second wall-plate, and the air inlet comprises at least one of a first air inlet or a second air inlet; the third side-surface faces the first wall-plate, and the fourth side-surface faces the second wall-plate; and the first air inlet is located on the first wall-plate, and the second air inlet is located on the second wall-plate.

5. The charging pile of claim 4, further comprising a third partition, wherein the third partition is connected to the first wall-plate, the third partition and the first wall-plate cooperatively define an air-inlet duct, the air-inlet duct communicates with the first air inlet, and the third partition is spaced apart from the first side-surface.

6. The charging pile of claim 4, wherein the air outlet comprises at least one of a first air outlet or a second air outlet, the first air outlet is located on the first wall-plate, and the second air outlet is located on the second wall-plate.

7. The charging pile of claim 4, wherein the first wall-plate and the second wall-plate each are an openable door.

8. The charging pile of claim 1, further comprising a centrifugal fan located between the second side-surface and the air outlet.

9. The charging pile of claim 1, further comprising a frame configured to fix the charging module.

10. The charging pile of claim 1, wherein sound insulation cotton is further disposed in the accommodating cavity, and is configured to absorb a noise in the accommodating cavity.
